(19) United States
(12) Patent Application Publication
(10) Pub. No.: US 2010/0117524 A1
(43) Pub. Date: May 13, 2010

(54) LIGHT EMITTING DEVICE

(75) Inventors: Dirk Hente, Wuersellen (DE); Wolfgang Otto Budde, Aachen (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/593,372

(22) PCT Filed: Apr. 1, 2008
(86) PCT No.: PCT/IB2008/051211

§ 371 Date: Sep. 28, 2009

(30) Foreign Application Priority Data
Apr. 4, 2007 (EP) 07105631.1

(51) Int. Cl. H01J 1/62

(52) U.S. Cl. 313/504

(57) ABSTRACT

The invention relates to a light emitting device (10), comprising a stack of layers (15) of a substrate, with a basic layer (20), a first electrode layer (30) and a second electrode layer (40), wherein an organic light-emitting layer (50) is sandwiched between the first electrode layer (30) and the second electrode layer (40), the organic light-emitting layer (50) is emitting an artificial light (51), the basic layer (20) is covered by a retroreflective member (60), structured in a first section (61) and a second section (62), a plurality of retroreflective elements (70,70′) are embedded in the first section (61), each retroreflective element (70,70′) reflects an ambient light (80,80′) falling onto a front side (65) of the retroreflective member (60) back in a direction of an origin of the ambient light (80,80′), the second section is transparent to the artificial light (51) falling onto a back side (66) of the retroreflective member (60).

### FIELD OF THE INVENTION

This invention relates to a light emitting device.

### BACKGROUND OF THE INVENTION

Construction workers or roadmen face a high danger of being overlooked by motorists or other road users during the nighttime. Thus, even while being illuminated by the automobile headlights the dark clothes of construction workers may not sufficiently emerge to prevent an accident. This is also true for the twilight, where car drivers are not using their automobile headlights and construction workers are often recognized too late to prevent an accident. The same applies for traffic signs, road signs or signposts. Often those signs are recognized too late by the motorist, so that a dangerous situation can occur if the motorist counteracts the order given by the sign. Serious consequences like the one described occur in many areas of the daily life, in which an overlooking of a badly illuminated or minor reflective object easily happens. To prevent those disadvantage the object or the person could be equipped with a light emitting device or a highly reflective outer layer.

In the U.S. Pat. No. 6,142,643 A an illumination device is described, which comprises an electroluminescence element to which a retroreflective layer is attached. Thus, the light emitting device provides both, a retroreflective effect as well as self-luminescence. Unfortunately, electroluminescence light sources are known to be costly and extremely inefficient. Furthermore, they need an AC power source and a voltage, which is usually high and potentially dangerous.

In the WO 2005/102783 A1 a license plate assembly is shown, comprising an OLED, which is covered by a retroreflective sheet. Unfortunately, retroreflective sheets have a high attenuation for the artificial light, being emitted by the OLED. So the described license plate assembly provides a retroreflective effect and a self-luminescence. Nevertheless, the achieved light output of the license plate assembly is due to the retroreflective member extremely low.

### SUMMARY OF THE INVENTION

The invention has for its object to eliminate the above mentioned disadvantages. In particular, it is an object to the invention to provide a DC driven light emitting device, which provides exceptional visibility at night.

The object of the invention is achieved by a light emitting device, comprising a stack of layers of a substrate, with a basic layer, a first electrode layer and a second electrode layer, wherein an organic light-emitting layer is sandwiched between the first electrode layer and the second electrode layer, the organic light-emitting layer is emitting an artificial light, the basic layer is covered by a retroreflective member, structured in a first section and a second section, a plurality of retroreflective elements are embedded in the first section, each retroreflective element reflects an ambient light falling onto a front side of the retroreflective member back in a direction of an origin of the ambient light, the second section is transparent to the artificial light falling onto a back side of the retroreflective member.

The leading thought of the invention is to use an OLED as an extremely efficient large area light source which can be driven by a DC current. By the combination of the OLED with an element which possesses retroreflective properties, a device is disclosed, which provides retroreflective effects as well as self-luminescence. Due to the segmentation of the retroreflective member in a first and second section, a sufficient light output is achieved. As a result, articles incorporating the described light emitting device such as road signs, or clothes can provide improved effectiveness and enhanced safety.

The light emitting device may comprise a substrate layer, serving as a carrier, which may be made of glass or organic material or from non transmittive material such as metal foils. Onto this substrate layer usually a thin layer of a transparent Indium Tin Oxide (ITO) is applied, forming the first electrode layer. Furthermore, organic light emitting diodes consists of at least one thin layer, with a layer thickness of approximately 5 to 500 nm of organic substances. The OLED is regularly covered with a layer of metal, like aluminum, forming the second electrode layer, whereas the metal layer features a thickness of approximately 100 nm and thus a thickness like the ITO-layer. Aluminum of such a thickness works as a mirror, such that the emission is through the transparent ITO first electrode layer and the transparent basic layer only. In the context of the invention, the term organic light-emitting layer comprises a single layer of an organic material as well as an element, build of several layers, comprising organic and inorganic material.

In the context of the invention, the term “basic layer” should not be confused with the term “substrate” often used in the description for OLEDs as the layer on which the electrode and/or organic layers are deposited. The basic layer in the sense of the invention may but must not be the substrate. For example, if a bottom emitting OLED is used, where the artificial light leaves the organic light-emitting layer through the substrate, basic layer and substrate are to be the same. In a case where a top emitting OLED is used, the basic layer may also be the coating sheet on top of one of the electrode layers. In both cases the basic layer is always the outer layer of the OLED through which the artificial light, generated in the organic light-emitting layer will leave the OLED.

The described layer structure forming an OLED is the active part of the enclosed light emitting device. Onto this stack of layers a retroreflective member is arranged, being the passive part of the light emitting device. The retroreflective member comprises a plurality of retroreflective elements. A retroreflective element possesses the ability to reflect light in the direction of its origin. Such kind of retroreflective elements may be made by placing three planes mutually perpendicular to one another. To prevent the retroreflective elements from attenuation the light flux, being emitted by the organic light-emitting layer, the disclosed light emitting device comprises a retroreflective member which comprises a first and a second section, but only the first section comprises the retroreflective elements. Both sections are positioned side by side, covering the basic layer of the stack of layers. Therefore, the artificial light emitted by the organic light-emitting layer can flow through the second section without being attenuated, absorbed or scattered. If therefore the light emitting device is used at night on a jacket of a roadman, the jacket is self-illuminating and therefore clearly visible for any person without the need of being actively illuminated. But in case the light of an automobile headlight strikes the light emitting device it will be reflected and therefore added to the artificial light emitted by the light organic layer. This results in a bright jacket, enabling the roadman to be recognized early and from a safe distance.

In the context of the invention the term “artificial light” describes the light being generated and emitted by the organic light-emitting layer. It is therefore the light produced within the light emitting device, being radiated to the outside. In the contrast the term “ambient light” comprises all light being radiated onto the light emitting device from the outside. The ambient light may have its origin from automobile headlights or other light sources, which radiate a light which is falling on the outer surface of the light emitting device. As the retroreflective member is part of the outer most layer of the described light emitting device any ambient light will fall onto the front side of the retroreflective member. The artificial light of the organic light-emitting layer will enter the retroreflective member through a back side, propagate through the member itself and leave it on the front side.

In a preferred embodiment the retroreflective member is connected with the basic layer. Depending on the material used for the retroreflective member different types of connections between the retroreflective member and the basic layer can be used. If the retroreflective member is a polymer, a cheap and easy connection between the two named films like structures can be achieved by gluing them together. To prevent scattering and attenuation the glue used should have an index of refraction which is more or less equal to that of the retroreflective member and/or the basic layer.

In another preferred embodiment the retroreflective member and the basic layer are one piece. This has the advantage that the artificial light has not to cross from the basic layer into the retroreflective member, which may produce scattering or losses at the crossing point. As the basic layer has to be light transparent, it may be made of glass. Afterwards, the retroreflective member respectively the retroreflective elements could be milled out of this glass layer. Subsequent, the one piece retroreflective member and the basic layer could be coated by a sealing layer embedding and therefore protecting the retroreflective elements. If a polymeric material is used for the basic layer, the one piece retroreflective member/basic layer can be made during the casting. This type of production is cheap and preferably in those cases, where large numbers of the light emitting devices are produced.

In another preferred embodiment the retroreflective member is a foil like structure, being mutually divided into first and second sections. Within the first sections the retroreflective elements are embedded into the surface of the retroreflective member. Those retroreflective elements may be obtained by one of the following two ways. The retroreflective elements can be formed by a set of three mutually perpendicular planes, which form a cube corner element. Retroreflective elements possessing a cube corner cube like structure have the advantage of being easily embedded into the front side of a film like retroreflective member. In a preferred embodiment the retroreflective elements are arranged in a uniform manner within the first section of the retroreflective member. To reduce the scattering of light being produced within the organic light-emitting layer the retroreflective member should possess a reflection index between 1.2 and 1.8. Such reflection index is found in polymers, which may be used for the production of the retroreflective member. Illustrative examples for suitable polymers include acrylics, epoxy-modified acrylics, polycarbonates, etc. Depending on the type of use the retroreflective elements may be arranged in a single or a multilayer manner within the retroreflective member. To protect the retroreflective elements a protection layer may cover the whole retroreflective member. Such kind of protection film may comprise a polymer such as polyesters, acrylics, polyurethanes, vinyl chlorides, polycarbonates, polyamides, polyvinyl fluorides, polybutyrates, and the like.

Another way to gain a retroreflective element is to use reflecting and refracting optical elements arranged so that the focal surface of the refractive element coincides with the reflective surface, typically a partially transparent sphere or a spherical mirror. Such kind of microspheres or microstructures can be incorporated into the retroreflective member.

As water and oxygen have a degrading effect to the organic light emitting material, OLEDs are often sealed by a protection film. In another preferred embodiment the retroreflective member seals the stack of layers of the light emitting device. The sealing protects the light emitting device from environmental impacts. Therefore, the light emitting device may be cladded with the retroreflective member as whole or just parts of it.

In another preferred embodiment not only the second section but also the first section is at least partially transparent to the artificial light falling onto the backside of the retroreflective member. To overcome the described disadvantages the invention discloses a retroreflective member possessing a first and a second section. The second section is transparent for the artificial light and therefore does not attenuate the light flux. Thus, the disclosed light emitting device is on the one hand emitting sufficient light to be seen even from a far distance and on the other hand is highly visible if illuminated by ambient light due to the retroreflective elements. To further enhance the brightness of the light emitting device the retroreflective members may be designed partially transparent for the artificial light. This aim may be achieved by arranging the retroreflective elements at a certain distance from each other so that in between the elements the artificial light can propagate without attenuation. Furthermore, the retroreflective elements may be designed in such a way, that they do not attenuate the artificial light propagating from the backside through the retroreflective member, whereas they reflect the ambient light falling onto the front side.

Depending on the field of use the ratio of the areas covered by the first respectively second section may vary. If the light emitting device is integrated in a signpost, it has shown to be appropriate that up to 70% of the basic layer are covered with the second section and just down to 30% are covered with the first section. This ratio will lead to a light emitting device which is foremost self illuminating. The embodiment enables the signpost to be viewed from a far distance without the necessity of ambient light emitted by automobile headlights. If on the other hand the light emitting device is used on the clothes of roadmen it has shown to be appropriate to increase the area covered with retroreflective elements. Therefore, the first section may cover up to 70% of the light emitting device. The remaining area—down to 30%—of the basic layer is then covered by the light transparent second section.

Apart from the ratio the arrangement of the first respectively second section on the basic layer may vary depending on the type of use. So sections with a rectangular geometry resulting in a striped distribution of the first and second sector have shown to be appropriate if used for clothes. In other embodiments the first respectively second section may possess an area of the few cm², possessing at least one of the following out shapes: triangular, pentagonal, hexagonal or octagonal. Depending on the chosen outer form different pattern of the first respectively second sections can be build. Each of the named outer forms has its own advantage concerning the active respectively passive visibility.

In another preferred embodiment the second section is built by a clearance within the retroreflective member. Therefore, no attenuation by the retroreflective member to the artificial light occurs. In fact the light, being emitted by the organic light-emitting layer is directly propagating into the surrounding.

In another preferred embodiment the retroreflective member is a multilayer foil. For example, the retroreflective member can comprise three different layers. Onto a first layer, forming the substrate, the retroreflective elements—forming the second layer—are sputtered and/or evaporated. To seal the so-formed stack of layer a third protection layer may complete the retroreflective member. The multilayer foil design has the advantage that for each layer individual and therefore optimal chosen materials can be used. Thus, the polymeric material used for the substrate layer may be chosen because of its known small attenuation of the artificial light. In contrast to that the material used to from the retroreflective elements may possess the needed stability to be long-lasting. Furthermore, the substrate layer and/or the inclusion of the retroreflective elements may improve the external quantum efficiency of the OLED device. This would result in an increase of the light output due to the usage of the retroreflective elements.

The aforementioned light emitting device, as well as claimed components and the components to be used in accordance with the invention in the described embodiments, are not subject to any special exceptions with respect to size, shape, material selection. Technical concepts known in the pertinent field can be applied without limitations. Additional details, characteristics and advantages of the object of the present invention are disclosed in the subclaims and the following description of the respective figures—which are an exemplary fashion only—showing preferred embodiments of the light emitting device according to the present invention.

Theses figures are:

### BRIEF DESCRIPTION OF THE DRAWINGS

FIG. 1 shows a cross-section through a light emitting device,

FIG. 2 shows a cross-section through a first embodiment of a retroreflective member,

FIG. 3 shows a second embodiment of the retroreflective member,

FIG. 4 shows the light emitting device in a bottom emitting embodiment,

FIG. 5 shows another cross-section of the retroreflective member,

FIG. 6 shows another embodiment of the light emitting device and

FIG. 7 shows a signpost comprising the light emitting device.

### DETAILED DESCRIPTION OF EMBODIMENTS

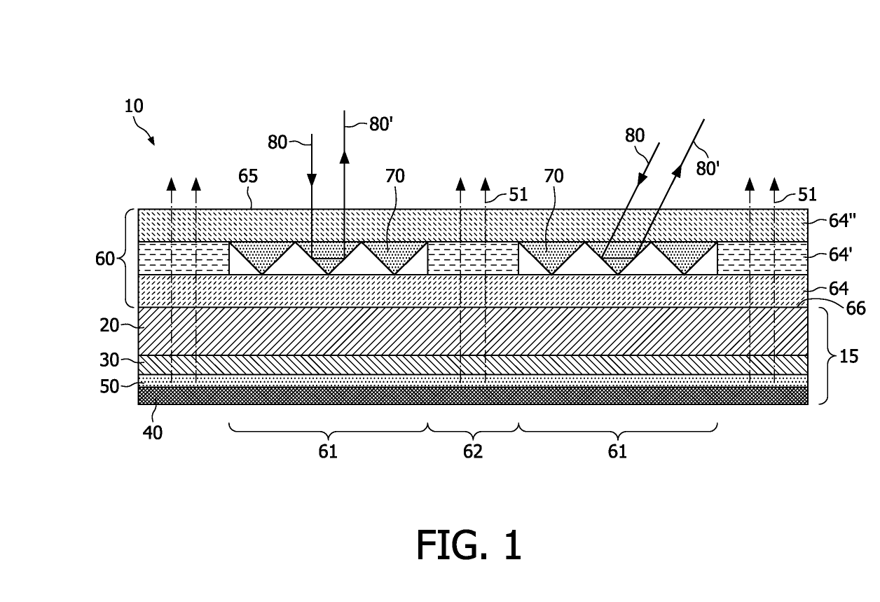

In FIG. 1 a cross-section of a light emitting device 10 is shown. The light emitting device 10 comprises a stack of layer 15 of a substrate. The fundament of the light emitting device 10 is formed by a basic layer 20, being a glass or polymer substrate. Deposited onto this basic layer 20 is a first electrode layer 30. Above this first electrode layer 30 an organic light-emitting layer 50 and a second electrode layer 40 are superimposed onto one another. Each of the three named layers 30, 40, 50 comprises a thickness of less than 500 nm, preferably about 50 nm to 200 nm. Upon application of an electrical current, flowing from the second electrode layer 40 to the first electrode layer 30 the organic light-emitting layer 50 radiates an artificial light 51 by recombination of electrons and holes in the organic material. The second electrode layer 40 is often built out of aluminum. Due to the fact that aluminum of the named thickness works as a mirror, the emitted artificial light 51 radiates through the transparent first electrode layer 30 and the basic layer 20. Such kind of organic light emitting diodes (OLED) are named bottom emitter because the artificial light 51 is radiated through the basic layer 20.

Aim of the invention was to increase security by disclosing a light emitting device 10 which on the one hand is self-illuminating and on the other hand possesses reflective properties. Furthermore, a DC current should be sufficient to drive the light source. Due to its high efficiency the described OLED, built out of the stack of layers 15 generates a light flux, which is clearly visible even over large distances. This is combined with a low energy consumption so that the light emitting device 10 can easily be embedded in clothes or road signs to enhance the safety.

To fulfill the second aim of the invention—achieve a reflective surface—the light emitting device 10 shown in FIG. 1 comprises a retroreflective member 60. This retroreflective member 60 comprises a plurality of retroreflective elements 70. To prevent attenuation of the artificial light 51 generated by the organic light-emitting layer 50 through the retroreflective elements 70, the retroreflective member 60 is divided in two sections. The first section 61 contains the plurality of the retroreflective elements 70. Therefore, the main aim of the first section 61 is to reflect an ambient light 80, 80′ falling onto a front side 65 of the retroreflective member 60. To achieve a high visibility spherical reflection alone would not be sufficient. Therefore, the retroreflective elements 70 possess the ability to reflect ambient light 80 back into a direction of the origin of the ambient light 80. If for example the light emitting device 10 is used in a signpost the described retroreflective elements 70 ensure that the reflected ambient light 80 reaches a driver of a car, illuminating this signpost.

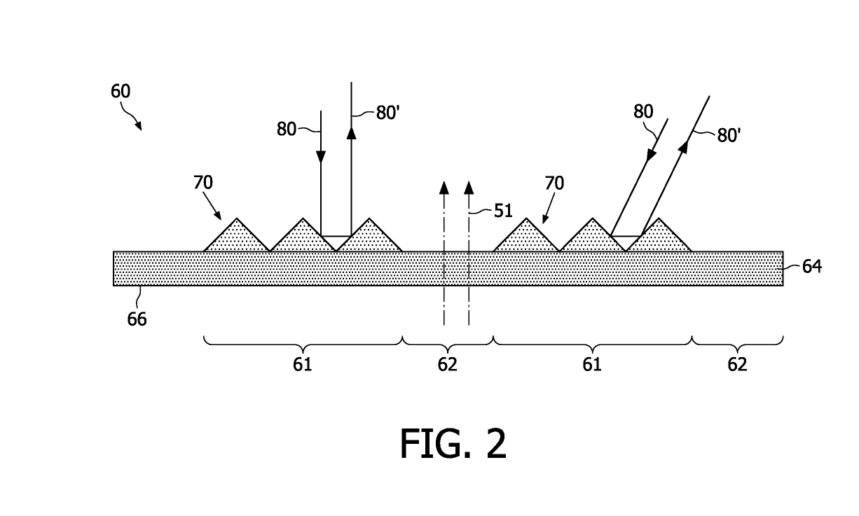

This capacity is also shown in FIG. 2, which only shows the retroreflective member 60. Onto a base foil 64 a plurality of retroreflective members 60 is arranged, each possessing a structure of three mutually perpendicular mirrors, which form a cube corner element. Ambient light 80 falling onto the front side 65 of the retroreflective member 60 is reflected on two of the surfaces of the retroreflective member 60. As a result the reflected ambient light 80′ propagates back in the direction of the origin of the ambient light 80. To achieve the needed high self-luminescence of the light emitting device 10 the base foil 64 possesses the second section 62, which is transparent to the artificial light 51 falling onto a back side 66 of the retroreflective member 60.

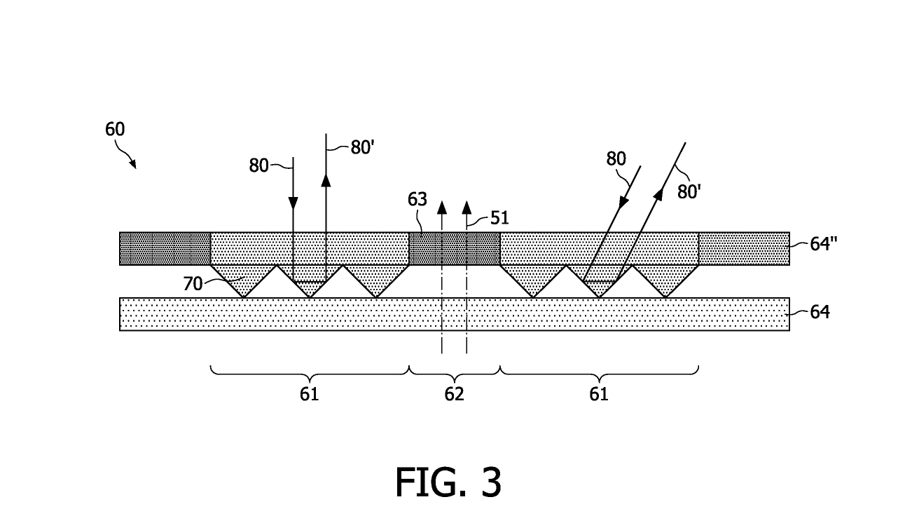

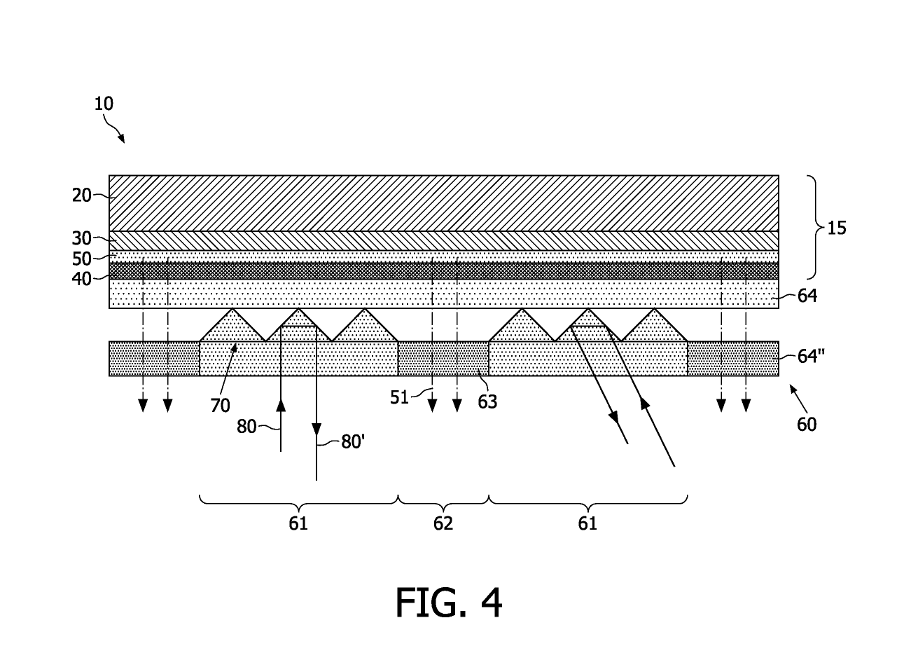

FIG. 3 shows another embodiment of the retroreflective member 60. It is also a foil like structure comprising a base foil 64 onto which the retroreflective elements 70 are applied. Together they form the first section 61 of the retroreflective member 60. To achieve a high transparency and therefore a low attenuation of the artificial light 51 the second section only comprises the basic layer 64. The second layer 64″ of the retroreflective element 70 is cut out. So a clearance 63 is formed through which the artificial light 51 propagates. The combination of the described retroreflective member 60 with the stack of layers 15 emitting the artificial light 51 is shown in FIG. 4.

In contrast to the light emitting device 10 described in FIG. 1 the shown stack of layers 15 emit the artificial light 51 through the second electrode 40 and not through the basic layer 20. Such kind of top emitting OLEDs can be formed by reducing the thickness of the second electrode layer 40. Below a certain thickness aluminum tends to become partially transparent. Therefore, the artificial light 51 generated within the organic light-emitting layer 50 can propagate through the second electrode layer 40 and leave the stack of layers 15. In the shown embodiment the artificial light 51 then flows through the retroreflective member 60. As it has been described the retroreflective member 60 possesses a clearance 63 forming the second section 62. Furthermore, retroreflective elements 70 are embedded onto the basic layer 64 forming the first section 61. The size and the shape of the sections 61, 62 depend on the usage of the disclosed light emitting device 10. For an easier understanding of the disclosed invention the first sections 61 in the shown embodiments are always larger than the second sections 62. This should not be understood as an exception with respect to size or shape.

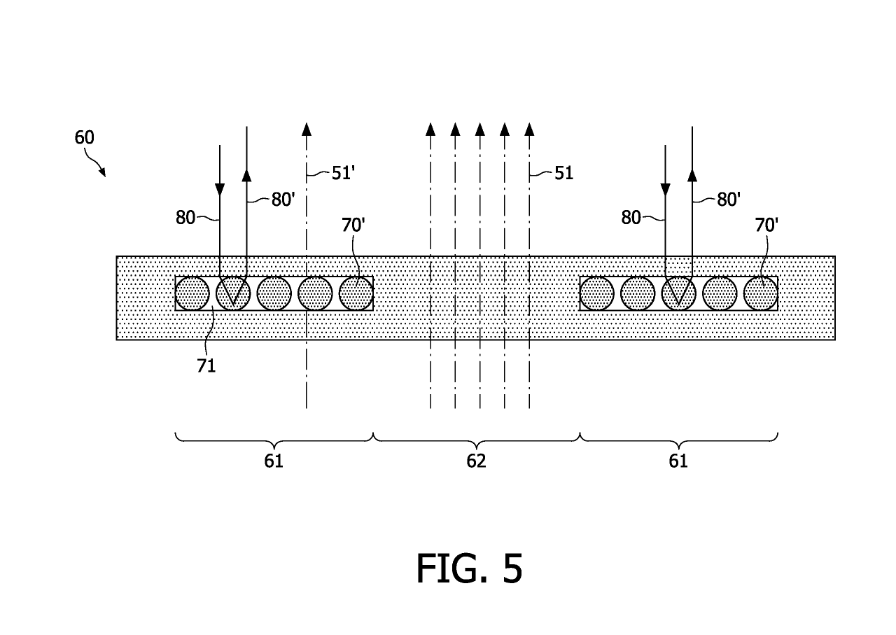

To achieve the needed reflection of the ambient light 80 the retroreflective member 60 shown in FIG. 5 possesses a plurality of bead like retroreflective elements 70′ with a reflective surface 71. Combined with the light transparent section 62 the shown retroreflective member 60 enables on the one hand a self-luminescence of the light emitting device 10 and on the other hand ensures that sufficient ambient light 80 is reflected so that high visibility is achieved. Furthermore, in the shown embodiment the retroreflective elements 70′ embedded in the first section 61 are at least partially light transparent. Therefore, also a part of the emitted artificial light 51′ is able to flow through the first section 61.

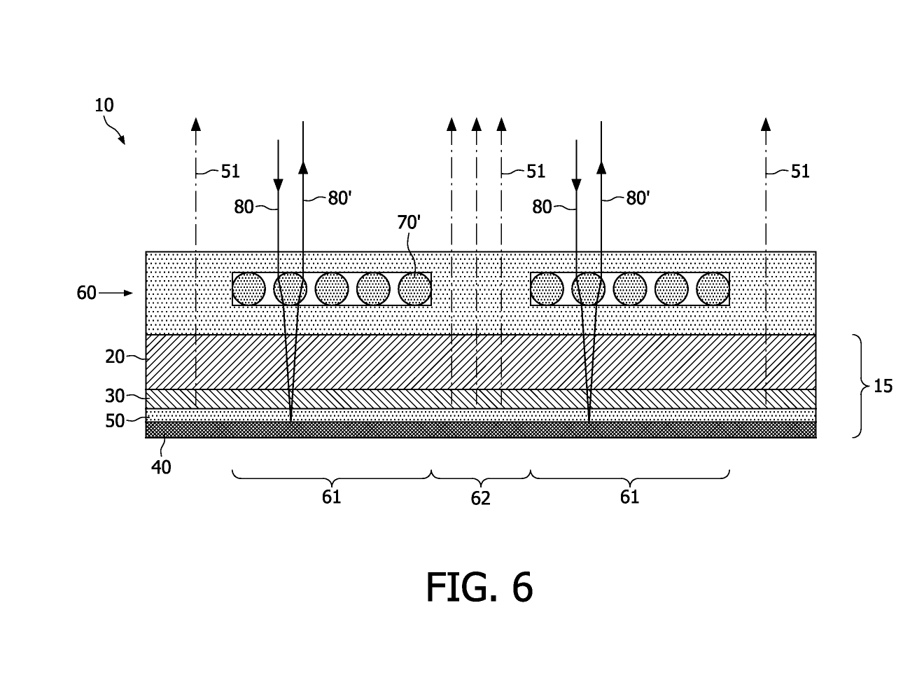

In FIG. 6 the light emitting device 10 is shown, comprising another embodiment of the retroreflective member 70′. The stack of layers 15 forms a bottom emitting OLED, generating the artificial light 51 propagating through the second section 62 and therefore enabling the light emitting device 10 to illuminate the surrounding and being seen by third persons. If, for example, such a device 10 is mounted onto the cloth of a roadman his security is strongly enhanced. As the light emitting device 10 only has low energy consumption and needs a DC voltage, the needed power supply can easily be embedded in the cloth. The emitted artificial light 51 enables a third person to view the roadman from a far distance. If on the other hand at night a car approaches, the ambient light 80 emitted by the automobile headlights falls onto the front side 65 of the light emitting device 10. To achieve the retroreflective properties the bead like retroreflective elements 70′ deflect the ambient light 80. In contrast to the retroreflective member 60 shown in FIG. 5 the ambient light is not reflected at the reflective surface 70, but at the second electrode layer 40. As the second electrode layer 40 is made of aluminum it works like a mirror, reflecting the ambient light 80′ back into the direction of the surface of the light emitting device 10. On its way out of the stack of layers 15 the ambient light 80′ again travels through one of the retroreflective element 70′, is again deflected and leaves the light emitting device 10 in the direction of its origin. The combination of the reflected ambient light 80′ and the artificial light 51 will guarantee a high visibility and a significant reduced chance of overlooking the roadman.

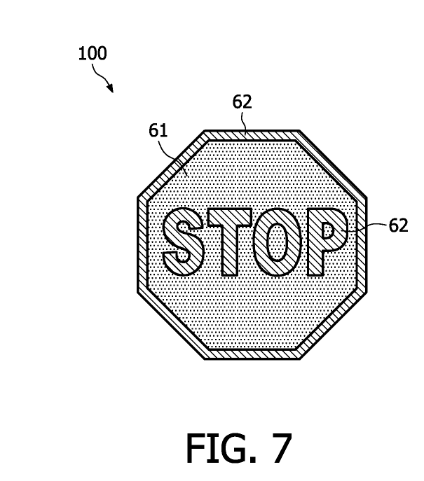

In FIG. 7 a signpost as a potential field of application for the disclosed light emitting device 10 is shown. The outer form of the signpost 100 and the information to be shown define the outer form of the first section 61 respectively the second section 62. In the shown embodiment the word “stop” and the outer border of the signpost 100 are formed by the transparent second section 62. Therefore, the word itself as well as the border of the signpost 100 is illuminated. Even at night a pedestrian or a cyclist will recognize the signpost 100 even from a far distance. If on the other hand a light source—for example a headlight of a car—illuminates the signpost 100 the reflected ambient light 80 will be added to the artificial light 51 emitted by the signpost 100. In any of the described cases the probability of overlooking the signpost 100 is strongly reduced.

### LIST OF NUMERALS

10 light emitting device
15 stack of layers
20 basic layer,
30 first electrode layer
40 second electrode layer
50 organic light-emitting layer
51,51′ artificial light
60 retroreflective member
61 first section
62 second section
63 clearance in the retroreflective member 60
64,64′,64″ foil
65 front side
66 back side
70,70′ retroreflective element
71 reflective surface
80,80′ ambient light
100 signpost

1. A light emitting device, comprising a multi-layered substrate, comprising
a basic layer,
a first electrode layer
a second electrode layer,
an organic light-emitting layer for emitting an artificial light, is the organic light-emitting layer disposed between the first electrode layer and the second electrode layer, and
a retroreflective member having a first section and a second section, wherein
the basic layer is at least partially covered by the retroreflective member and wherein
a plurality of retroreflective elements are embedded in the first section, each retroreflective element capable of reflecting an ambient light falling onto a front side of the retroreflective member the second section being transparent to the artificial light falling onto a back side of the retroreflective member.

2. A light emitting device according to claim 1, wherein the retroreflective member is connected with the basic layer Or forms an integral structure therewith.

3. A light emitting device according to claim 1, wherein the retroreflective element comprises three mutually perpendicular planes, forming a cube corner element.

4. A light emitting device according to claim 1, wherein the retroreflective elements are microspheres, incorporated into the retroreflective member.

5. A light emitting device according to claim 1 wherein the retroreflective member seals the multi-layered substrate.

6. A light emitting device according to claim 1 wherein the first section is at least partially transparent to the artificial light falling onto the back side of the retroreflective member.

7. A light emitting device according to claim 1, wherein the first and/or the second section have at least one of the following outer shapes: triangular, foursquare, pentagonal, hexagonal, or octagonal.

8. A light emitting device according to claim 1, wherein the second section is a void formed in the retroreflective member.

9. A light emitting device according to claim 1 wherein the retroreflective member is a multilayer foil.
